(19) United States
(12) Patent Application Publication
(10) Pub. No.: US 2006/0125493 A1
(43) Pub. Date: Jun. 15, 2006

(54) Corrosion sensor and method of monitoring corrosion

(75) Inventors: Vivek Subramanian, Orinda, CA (US); James Intrater, Vienna, VA (US); Tirumalai S. Sudarshan, Vienna, VA (US); Mohamed Raffi Sahul Hameed, McLean, VA (US)

Correspondence Address: DINESH AGARWAL, P.C., 5350 SHAWNEE ROAD, SUITE 330, ALEXANDRIA, VA, 22312, US

(73) Assignee: MATERIALS MODIFICATION, INC.

(21) Appl. No.: 11/008,937

(22) Filed: Dec. 13, 2004

(51) Int. Cl. G01R 27/08

(52) U.S. Cl. 324/700

(57) ABSTRACT

A method of monitoring corrosion and corrosion sensor includes a first element including a corrodible element to be exposed to a corrosive or corrosion-suspect environment, and a second element including a corrosion sensing circuit coupled with the corrodible element for generating a wireless signal based on the corrosion of the corrodible element.

### BACKGROUND OF THE INVENTION

The present invention is generally directed to a sensor, and more particularly to a corrosion sensor and method of monitoring corrosion.

Numerous materials in common use are degraded through corrosion processes by interactions with other materials present in their ambient. For example, metals such as iron often corrode through exposure to oxygen and moisture. Such corrosion processes often cause damage to equipment and structures fabricated from these materials, leading to reduced equipment life and reliability. To minimize the undesirable consequences of corrosion on product usability, reliability, and lifetime, it is often desirable to replace corroded materials before they reach a critical level of corrosion. For example, some portions of vehicles are more prone to corrosion than others; metallic sections towards the bottom of vehicles often show more corrosion than metallic sections towards to the top of the same. In this case, it is desirable to replace the corroded bottom sections before they degrade to the point that they affect the functioning and/or reliability of the entire vehicle.

As a result, there has been tremendous interest in the development of sensors for monitoring corrosion. Such sensors could be used to detect corrosion before it reaches critical levels, thus allowing the appropriate corrective actions to be performed. In particular, there has been great interest in the development of corrosion sensors that can be used in-situ. Such sensors can be placed into the same environment and be exposed to the same corroding mechanisms as the structure to be monitored. By continuously or periodically checking the status of the sensor, it is possible to obtain a measurement of the level of corrosion likely to be present in the structure in question. The prior art discloses several such devices.

U.S. Pat. No. 4,295,092 discloses an apparatus and method for detecting and measuring corrosion damage in pipes by measuring capacitance, and U.S. Pat. No. 6,186,191 monitors the functionality of flexible pressure hoses in a loom.

One of the most common techniques for corrosion sensing is resistance sensing, wherein the change in electrical resistance in a corroding element is used to characterize the cumulative corrosion. Such a corrosion sensor is disclosed by S. T. Stropki et al., Proceedings of the 1989 Tri-service Conference on Corrosion, Report NADC-SIRLAB-1089, V. S. Agarwala, Ed., published by Defense Logistics Agency, Alexandria, Va., 1989, p. 544-561. Resistance-based corrosion sensors have also been disclosed in U.S. Pat. Nos. 6,564,620, 5,627,749, 5,977,782, 4,839,580, 4,780,664, and 4,755,744. The use of electrical resistance has also been combined with linear polarization resistance measurements to enable simultaneous measurement of cumulative corrosion and instantaneous corrosion rates, as disclosed by F. Ansuini, NADC-SIRLAB-1089, pp. 533-543.

Several sensors are also known that use electrochemical impedance spectroscopy methodologies. For example, electrochemical impedance spectroscopy using a semi-liquid electrolyte cell is disclosed by Kihira et al, U.S. Pat. No. 4,806,849, and using a spongy medium soaked with a liquid electrolyte in Kondou et al, U.S. Pat. No. 5,221,893. Electrochemical impedance spectroscopy-based corrosion sensing is disclosed in U.S. Pat. Nos. 6,054,038 and 6,328,878. U.S. Pat. No. 6,313,646 discloses the use of electrochemical impedance spectroscopy to detect degradation caused by excessive moisture uptake using composite laminations, honeycomb or adhesively bonded structures.

In addition to electrical impedance and resistance measurement techniques, several other techniques for corrosion characterization have also been made available. U.S. Pat. No. 5,286,357 discloses the measurement of corrosion through the measurement of electrochemical noise between electrodes contacting the sensing surface. U.S. Pat. No. 6,490,927 discloses the use of ultrasonic or radio-frequency signals sent from a metal probe contacting the surface to perform corrosion characterization. Reflections of the signals that result at corroded regions are measured to characterize the extent of corrosion. Agarwala discloses a sensor based upon the effects of galvanic corrosion, for atmospheric marine environments (see V. S. Agarwala, “Corrosion Monitoring of Shipboard Environments”, ASTM Special Technical Publication 965, S. W. Dean and T. S. Lee, Eds., ASTM, 1986, pp. 354-365). U.S. Pat. No. 5,367,583 discloses the characterization of corrosion using optical sensing techniques. The corrosion sensor acts as a mirror in a fabry-perot cavity; corrosion-induced changes in reflectance are measured optically to determine the extent of corrosion. U.S. Pat. No. 6,144,026 discloses an optical corrosion characterization technique. Corrosion sensor systems are formed by using one or more fiber gratings whose transverse strains vary with corrosion or chemical attack. By optical probing, it is therefore possible to determine the corrosion along the fiber. U.S. Pat. No. 5,948,971 discloses a pressure-based corrosion measurement technique. A membrane is stretched across a cavity. Upon corrosion-induced rupture of the membrane, the resulting pressure change in the cavity may be measured to detect the corrosion.

In general, the electrical measurement techniques, including resistance measurement and electrochemical impedance measurement offer advantages in terms of their simplicity and applicability. Unlike the optical techniques and the pressure-based techniques, which require specific geometric constructs, the electrical techniques may usually be achieved using planar sensors placed on the surface of objects to be characterized. These sensors therefore have the advantage of being exposed to similar flows, etc. as the surface in question, and therefore, may provide more representative corrosion characterization data. Furthermore, electrical data is typically read, interpreted, and stored more easily than optical or pressure data, which usually must be subsequently converted to electrical form using some form of transducer.

The prior art electrical sensor techniques and apparatus suffer from a major shortcoming; they require electrical connection to the sensor, and therefore require that the reader used to determine the state of the sensor be placed in direct physical contact with the sensing element. In the resistance measurement techniques, this requires the use of wires running from the corrosion sensor to a reader circuit. In the impedance techniques, similar electrical connections are also required. The information read from a sensor is communicated over the wires. In U.S. Pat. No. 5,627,749, the resistance sensor is read and the data is stored in a central processing unit with associated solid-state memory. This unit is physically connected to the sensor using wires, and is powered by a battery or electrical power source. Similarly, U.S. Pat. Nos. 5,977,782, 4,839,580, 4,780,664, and 4,755,744, also require a direct electrical contact to the resistance sensor.

The need for a direct electrical or physical contact is a serious drawback, as it limits the placement of sensors to regions that are easily queried with direct electrical connections. Implementation of such a sensing system in buried or hidden surfaces would require the installation of routing wires, increasing complexity and cost. U.S. Pat. No. 6,564,620 eliminates the need for a direct electrical connection to the sensor by integrating a display unit into the sensor apparatus, such that the integrated sensor system provides a visual indication of corrosion. Power for the display and sensor is provided by a battery or even using inductive coupling from an external radio-frequency (RF) source. An external source is also used to turn the sensor on as required, thus conserving power when not needed. However, the disadvantage of this technique is that it requires visual access to the display mechanism to read the state of the sensor, and is therefore not usable in systems where no surface is conveniently viewable by the user, such as the underside of an automobile.

In view of the drawbacks associated with conventional devices and techniques, there is a need in the industry for a corrosion sensor, which is simple in design, easy to read even when access is difficult, and does not require direct electrical and/or physical contact.

### OBJECTS AND SUMMARY OF THE INVENTION

The principal object of the present invention is to provide a corrosion sensor which overcomes the drawbacks associated with conventional devices.

Another object of the present invention is to provide a corrosion sensor which communicates without the need for physical, visual, or electrical contact.

Yet another object of the present invention is to provide a corrosion sensor which can be placed in regions that are not easily accessible with physical, visual, or electrical contact.

An additional object of the present invention is to provide a corrosion sensor which provides easily read, interpreted and stored electrical data.

Yet an additional object of the present invention is to provide a corrosion sensor which may be conveniently formed as a flexible circuit that may be mounted on a surface susceptible to corrosion, and exposed to the same corroding mechanism or environment that affect the surface to be monitored.

Another object of the present invention is to provide a corrosion sensor which is simple in design and easy to manufacture.

Yet another object of the present invention is to provide a corrosion sensor which monitors corrosion.

A further object of the present invention is to provide a corrosion sensor which can detect, monitor, or otherwise test the presence of a corrosive environment.

Yet a further object of the present invention is to provide a method for detecting, monitoring, or otherwise testing corrosion.

In summary, the main object of the present invention is to provide a corrosion sensor and method, which can be used to monitor corrosion in difficult to reach areas without requiring direct electrical and/or physical contact.

One of the above objects is met, in part, by the present invention, which in one aspect includes a corrosion sensor including a first element including a corrodible element to be exposed to a corrosive or corrosion-suspect environment, and a second element including a corrosion sensing circuit coupled with the corrodible element for generating a wireless signal based on the corrosion of the corrodible element.

Another aspect of the present invention includes a corrosion sensor including a first circuit for generating a wireless signal based on the extent of corrosion and a second circuit for receiving the wireless signal.

Another aspect of the present invention includes a corrosion sensor including first and second circuits. The first circuit includes a first element having a corrodible conductor, a second element for generating an electromagnetic signal based on the corrosion of the corrodible conductor, and a third element for storing an electric charge. The second circuit is provided for receiving the electromagnetic signal.

Another aspect of the present invention includes a corrosion sensor including first and second circuits. The first circuit includes a first element having a corrodible conductor, a second element for generating an electromagnetic signal, a third element for strong an electric charge, and a fourth element for changing the frequency of the electromagnetic signal based on the corrosion of the corrodible conductor. The second circuit is provided for receiving the electromagnetic signal.

Another aspect of the present invention includes a corrosion sensor including first and second circuits. The first circuit includes a first element having a corrodible conductor, a second element for generating an electromagnetic signal having a first frequency, a third element for storing an electric charge, and a fourth element for creating a second frequency within the electromagnetic signal based on the corrosion of the corrodible conductor. The second circuit is provided for receiving the electromagnetic signal.

Another aspect of the present invention includes a corrosion sensor including first and second circuits. The first circuit includes a first element having a corrodible conductor, a second element for supplying power to the first circuit, and a radio-frequency identification member for generating a wireless signal. The second circuit is provided for receiving the wireless signal.

Another aspect of the present invention includes a corrosion sensor circuit including a conductor to be exposed to a corrosive or corrosion-suspect environment, which has a resistance value that varies as the conductor is corroded. A wireless signal generator is coupled to the conductor for generating a signal based on the resistance value of the conductor.

Another aspect of the present invention includes a method of monitoring corrosion, which includes providing a corrodible conductor having a resistance value that varies as the conductor is corroded, coupling a wireless signal generator to the conductor, exposing the conductor to a corrosive or corrosion-suspect environment, and generating a signal based on the resistance value of the conductor to determine corrosion.

Another aspect of the present invention includes a method of monitoring corrosion, which includes providing a corrodible conductor having a resistance value that varies as the conductor is corroded, coupling a wireless signal absorber to the conductor, coupling a power storing member to the absorber, sending a radio-frequency signal to the absorber, and measuring the amount of absorption to determine corrosion.

Another aspect of the present invention includes a method of monitoring corrosion, which includes providing a corrodible conductor having a resistance value that varies as the conductor is corroded, coupling a wireless storage generator to the conductor, coupling a power storing member to the generator, sending a radio-frequency signal to the generator, and generating a signal based on the resistance value of the conductor to determine corrosion.

Another aspect of the present invention includes a method of monitoring corrosion, which includes providing a corrodible conductor having a resistance value that varies as the conductor is corroded, coupling a wireless signal generator to the conductor, coupling a power storing member to the generator, coupling a frequency altering member to the conductor and the generator, sending a radio-frequency signal to the generator, and generating a signal of altered frequency based on the resistance value of the conductor to determine corrosion.

Another aspect of the present invention includes a method of monitoring corrosion, which includes providing a corrodible conductor having a resistance value that varies as the conductor is corroded, coupling a wireless signal generator to the conductor, coupling a power storing member to the generator, coupling a harmonic frequency member to the conductor and the generator, sending a radio-frequency signal to the generator, and generating a harmonic frequency based on the resistance value of the conductor to determine corrosion.

Another aspect of the present invention includes a method of monitoring corrosion, which includes providing a corrodible conductor having a resistance value that varies as the conductor is corroded, coupling a power supply to the conductor, coupling a radio-frequency identification member for generating a wireless signal to the conductor and the power supply, disconnecting the radio-frequency identification member based on the resistance value of the conductor, and generating a wireless signal to determine corrosion.

Another aspect of the present invention includes a method of monitoring corrosion, which includes providing a plurality of corrodible conductors each having a resistance value that varies as the conductor is corroded, coupling a power supply to each conductor, coupling a radio-frequency identification member to the power supply, connecting the conductors between pairs of inputs on the radio-frequency identification member, and generating a wireless signal having a frequency based on the resistance value of one of the conductors.

Another aspect of the present invention includes a method of monitoring corrosion, which includes providing a plurality of corrodible conductors each having a resistance value that varies as the conductor is corroded, coupling a power supply to the conductor, coupling a radio-frequency identification member to the power supply, connecting the conductors between a single input on the radio-frequency identification member and a common terminal, and generating a wireless signal having a frequency based on the resistance value of one of the conductors.

### BRIEF DESCRIPTION OF THE DRAWINGS

One of the above and other objects, novel features and advantages of the present invention will become apparent from the following detailed description of the preferred embodiment(s) of invention, illustrated in the accompanying drawings, wherein:

FIG. 1 is a schematic illustration of a corrosion sensor of the present invention;

FIG. 2 is a schematic illustration of a second embodiment of the corrosion sensor of the present invention;

FIG. 3 is a schematic illustration of the corrosion sensor of FIG. 2, shown with multiple resonant circuits;

FIG. 4 is a schematic illustration of a third embodiment of the corrosion sensor of the present invention;

FIG. 5 is a schematic illustration of the corrosion sensor of FIG. 4, shown with multiple sensing elements and one base circuit;

FIG. 6 is a schematic illustration of a fourth embodiment of the corrosion sensor of the present invention;

FIG. 7 is a schematic illustration of a fifth embodiment of the corrosion sensor of the present invention;

FIG. 8 is a schematic illustration of a sample sensor circuit fabricated in accordance with the present invention;

FIG. 9 is a top plan view of a corrosion sensor made in accordance with the present invention; and

FIG. 10 is a longitudinal cross-sectional view taken along line 10-10 of FIG. 9.

### DETAILED DESCRIPTION OF THE PREFERRED EMBODIMENT(S)OF THE INVENTION

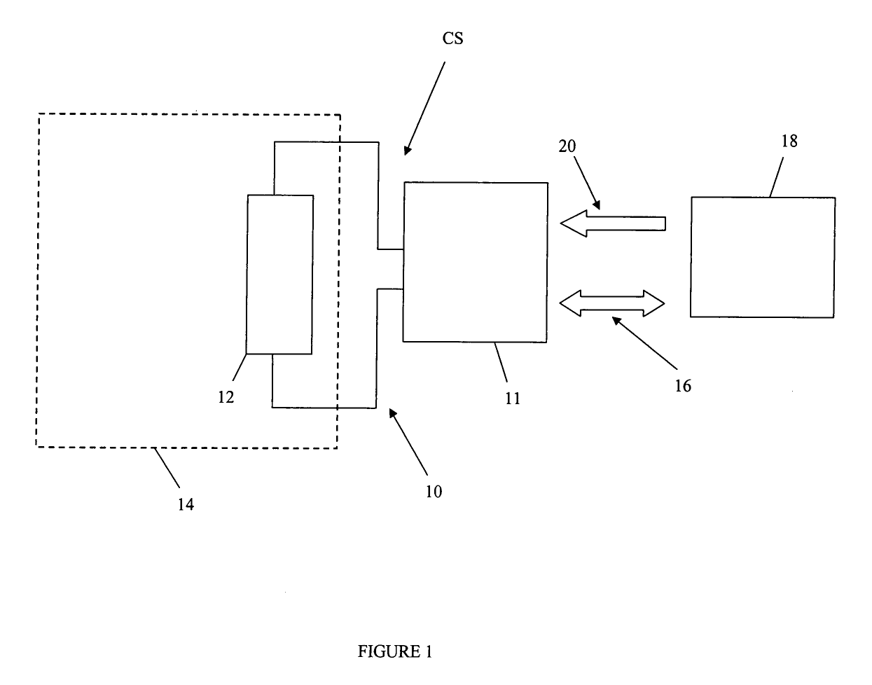

A schematic illustration of a corrosion sensor CS of the present invention is provided in FIG. 1, which monitors corrosion by resistive sensing and communication of the level of corrosion to a user without requiring a direct electrical or physical connection from, or direct visual access to a structure or surface to be monitored.

The corrosion sensor CS includes a sensor circuit 10, and a reader circuit 18 in proximity or remote therefrom. The reader circuit 18 (preferably a handheld apparatus with an external antenna to read a sensor out of the line-of-sight of a user, and sensitive to an appropriate output signal) sends an input (preferably radio-frequency) signal 20 to the sensor circuit 10, which may then use the input signal 20 to power the operation of the sensor circuit 10. The reader circuit 18 then communicates with the sensor circuit 10 to determine whether the sensor circuit 10 is emitting an output signal 16, or varying its absorption of the input signal 20.

The sensor circuit 10 includes a communication circuit 11 and a sensing element 12. The sensing element 12 includes a conductive, corrodible material, preferably in the form of one or more thin strips of metal, to be exposed to a corrosive environment 14, representative of the environment to be monitored. The communication circuit 11, preferably a radio-frequency circuit, is coupled to the sensing element 12, preferably in series, and is affected by the change in state of the sensing element 12. One or more electrical pathways in the communication circuit 11 are either activated or inactivated and, as a result, the communication circuit 11 varies the absorption of the input signal 20, or varies the characteristics or existence of the output signal 16. Accordingly, the state of the sensing element 12, at any given time, may be determined by placing the reader circuit 18 in proximity to the sensing circuit 10.

The choice of the conductive material for the sensing element 12 is based on the corrosion process to be monitored. Typically, the material is similar or identical to the corroding structure or surface to be monitored. The thickness of the sensing element 12 is selected such that, when corroded through, the state of the corroding structure or surface is at a critical point in need of identification. As the conductive material forming the sensing element 12 corrodes, its resistance value increases, or its resistive state varies. Upon complete corrosion, the sensing element 12 becomes an open circuit. Thus, the sensing element 12, preferably includes a strip of material that is primarily conductive, but becomes primarily non-conductive when corroded through. In this regard, it is noted herewith that the non-conductive state is a state in which the resistance measured across the conductive material is significantly higher than the resistance of an uncorroded strip of similar dimensions.

The sensing element 12 is coupled to the communication circuit 11, such that the output signal 16 of the sensor circuit 10 depends on the resistive state of the sensing element 12.

In order to monitor or determine the state of the sensing element 12, at any given time, the reader circuit 18 sends an input signal 20 to the sensor circuit 10, which uses this input signal 20 to power the operation of the sensor circuit 10. The sensor circuit 10 either varies the absorption of the incident input signal 20 based on the state of the sensing element 12, or emits the output signal 16, whose characteristics depend on the state of the sensing element 12. Dependent on the output signal 16 emanating from the sensor circuit 10, or dependent on a load imposed on the reader circuit 18 by the sensor circuit 10, the state of the sensing element 12 is determined by the corrosion sensor CS.

Multiple sensing elements 12 may be combined to ensure redundancy of data, thereby improving accuracy. Furthermore, multiple sensing elements 12 of different thicknesses may be used in conjunction with multiple communication circuits 11, which may be interconnected or separate, to enable the detection of multiple levels of corrosion. For instance, a thin sensing element would corrode first, indicating partial corrosion, while a thicker sensing element 12 would corrode later, indicating increased corrosion. This information may then be fed back to the user in a variety of ways, including, but not limited to, communication through a display, through a network connection, or through an electrical signal sent to a processing unit (not shown).

The sensor circuit 10 may optionally be formed on a thin planar circuit board construct. More specifically, the communication circuit 11 may be formed using conductive traces on a printed circuit board, connected by surface-mounted components, as appropriate. The sensing element 12 may be mounted to the board using conventional surface mounting techniques. The sensor circuit 10 may therefore be made flat, and may further be made flexible by using thin board materials. The sensor circuit 10 may therefore conveniently be mounted on a representative corroding surface without significantly altering the profile or geometry of the surface. As required, portions of the sensor circuit 10 may be protected with a protective encapsulation layer to ensure that inappropriate parts of the circuit are not corroded in the corrosive environment 14. Furthermore, as required, the sensor circuit 10 may be placed over materials of specifically chosen electromagnetic properties to enhance their performance. For example, the sensor circuit 10 may be placed over one or more thin layers of ferrite material to enable its operation on metallic surfaces. In ordinary use, the range of an electromagnetic resonant-circuit based communication system may be dramatically degraded by placing the sensor circuit 10 directly on metal. The use of a shielding layer, such as a ferrite tape between the sensor circuit 10 and the metal, would improve the operation of the corrosion sensor CS, if necessitated by the intended application.

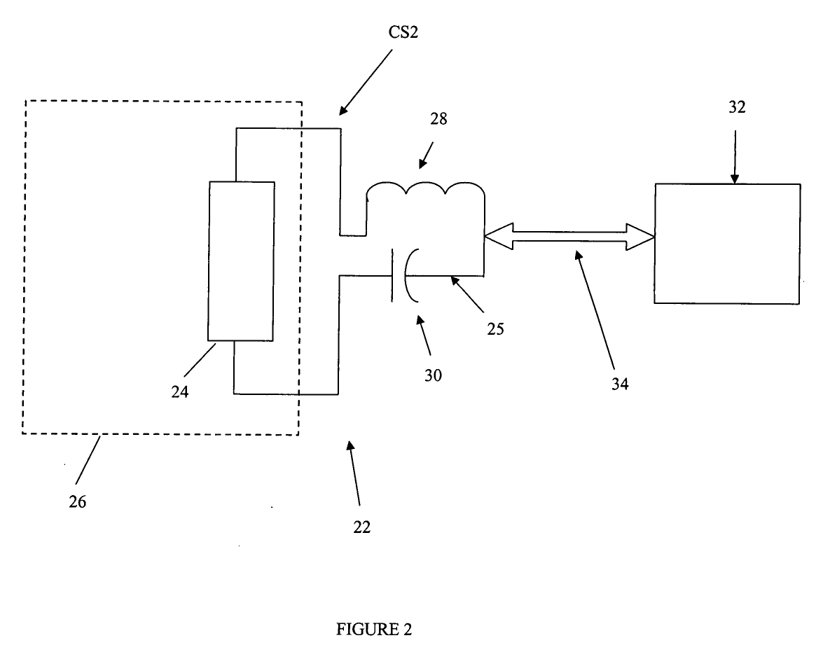

In a second embodiment (FIG. 2), a sensing element is preferably inserted in series with a communication circuit. When the sensing element is conductive, the communication circuit resonates with a reader-transmitted signal of the appropriate frequency. Upon corrosion of the sensing element, the resonance ceases, which may be detected by examining the load imposed on a reader circuit by the communication circuit 25, or by examining the ringing that results from the resonance.

As shown schematically in FIG. 2, the second embodiment of the corrosion sensor CS2 includes a sensor circuit 22, having a sensing element 24 to be exposed to a corrosive or corrosion-suspect environment 26, placed in series with a communication circuit 25. The communication circuit 25 includes an inductor 28 and a capacitor 30. When the sensing element 24 is uncorroded, the sensor circuit 22 forms an LC resonant circuit, whose resonant frequency is a function of the values of the inductor 28 and capacitor 30. In this embodiment, a reader circuit 32 preferably includes a radio-frequency circuit designed to emit an output radio-frequency signal 34 at and/or near the resonant frequency of the sensor circuit 22. When the sensing element 24 is resistive and therefore corroded to a critical level, the sensor circuit 22 does not absorb the input radio frequency signal 34. However, when the sensing element 24 is conductive and therefore not corroded to the critical level, the sensor circuit 22 absorbs the input radio frequency signal 34 strongly at the resonant frequency. The reader circuit 32 is preferably equipped with a detection circuit to detect this absorption. Detection of the absorption is indicative of an uncorroded or partially corroded sensing element 24. Absence of the absorption is indicative of an open circuit and thus the corroded sensing element 24. The detection circuit may communicate this information to a user through a variety of conventional visual, audible, and/or electrical means.

When the corrosion sensor CS2 is used in the above manner, it is preferable that the reader circuit 32 be placed in reasonably close proximity to the sensing element 24; typically, a range of a few inches to a few feet is achievable, depending on the sensitivity of the detection circuit and the shape and size of the inductor 28 and/or capacitor 30, and antenna in the sensor circuit 22 and reader circuit 32. In order to further enhance range, it is possible to stimulate the sensor circuit 22 by using one or more bursts of input radio-frequency signals 34 emanating from the reader circuit 32. The sensor circuit 22 will “ring”, emitting output radio frequency signals 34, for a few cycles after the burst is complete, which can be detected by the detection circuit in the reader circuit 32.

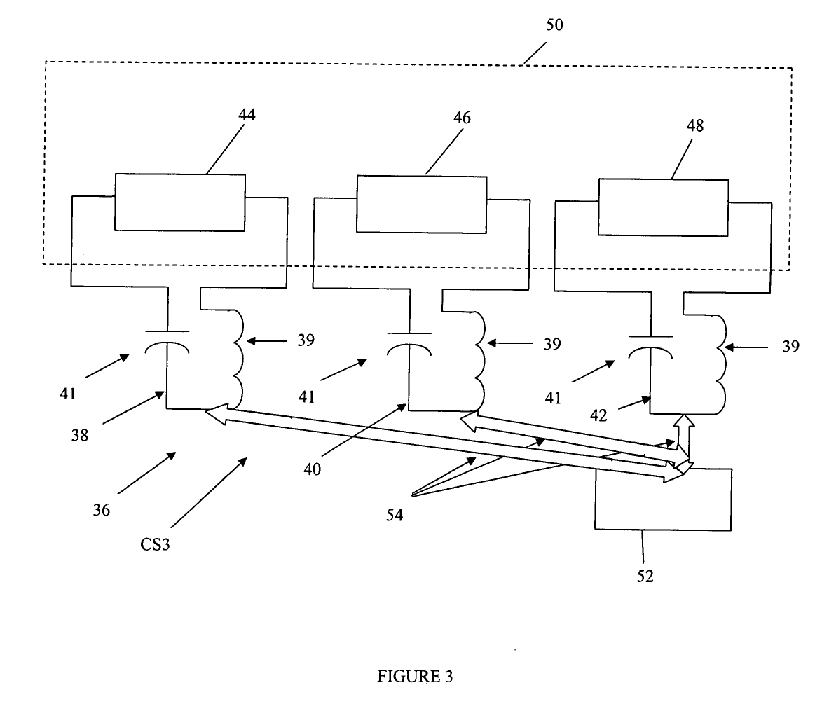

In order to detect multiple levels or grades of corrosion, multiple sensor circuits with different resonant frequencies may be used, each with a sensing element of a different thickness. A reader circuit could then test the different resonant frequencies to determine the state of each of the individual sensing elements, and hence enable the detection of the state of corrosion in multiple steps. An embodiment of such corrosion sensor CS3 is shown schematically in FIG. 3. As shown, a sensor circuit 36 includes preferably three communication circuits 38, 40 and 42, each including an inductor 39 and a capacitor 41, that function as three LC resonant circuits with different resonant frequencies and are placed in series with corresponding corroding or sensing elements 44, 46 and 48 of different thicknesses and exposed to a common corrosive or corrosion-suspect environment 50. A reader circuit 52 measures the absorption or emittance of signals 54 at the different resonant frequencies to determine the state of corrosion of the sensing elements 44, 46 and 48.

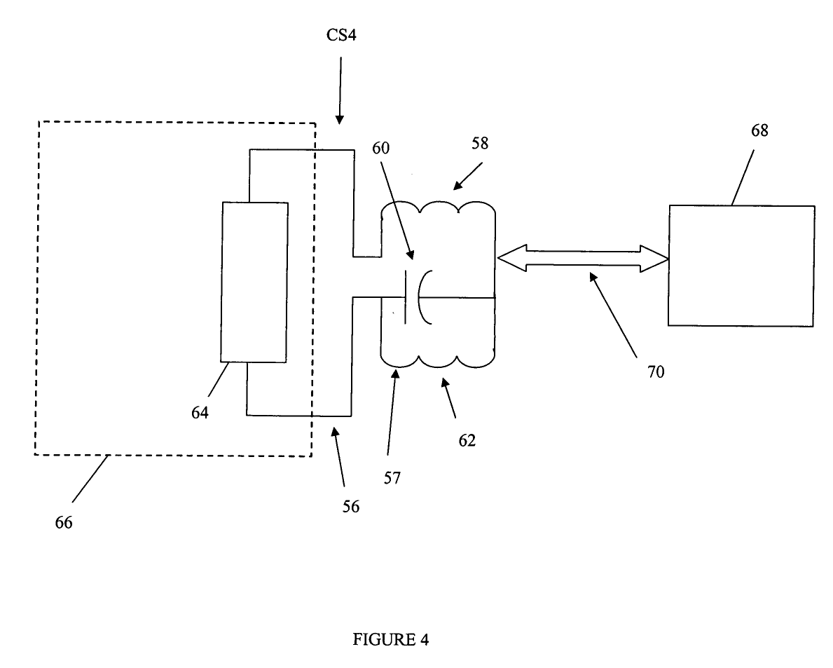

In a fourth embodiment of the corrosion sensor CS4, shown schematically in FIG. 4, a sensing element preferably switches a capacitor or inductor into a communication circuit. Based on the state of the sensing element, the resonant frequency of the communication circuit is changed, which may be detected by a reader circuit. As shown, a sensor circuit 56 includes a communication circuit 57 functioning as a resonant circuit and including an inductor 58 and a capacitor 60 in series, and an additional inductor or capacitor 62 in parallel. The sensing element 64 is placed in series with the additional inductor or capacitor 62 and is exposed to a corrosive or corrosion-suspect environment 66. When the sensing element 64 is uncorroded and therefore conductive, the resonant frequency of the sensor circuit 56 would be a function of all the inductors and capacitors 58, 60 and 62, as would be apparent to those skilled in the art. However, when the sensing element 64 is corroded and therefore nonconductive, the additional inductor or capacitor 62 would be open-circuited and the resonant frequency of the sensor circuit 56 would be a function of the primary resonant circuit only, i.e., the inductor 58 and capacitor 60. Alternatively, the communication circuit 57 may include the additional inductor or capacitor 62 in parallel with the sensing element 64 such that the additional inductor or capacitor 62 becomes short-circuited when the sensing element 64 is uncorroded and contributes to the resonant frequency of the sensor circuit 56, when the sensing element 64 is corroded.

Reading is performed in a manner similar to the second embodiment of the corrosion sensor CS2 described above, by using a reader circuit 68, either to measure loading at one or both of the two possible resonant frequencies, or to measure ringing at one or both of these frequencies of the signal 70.

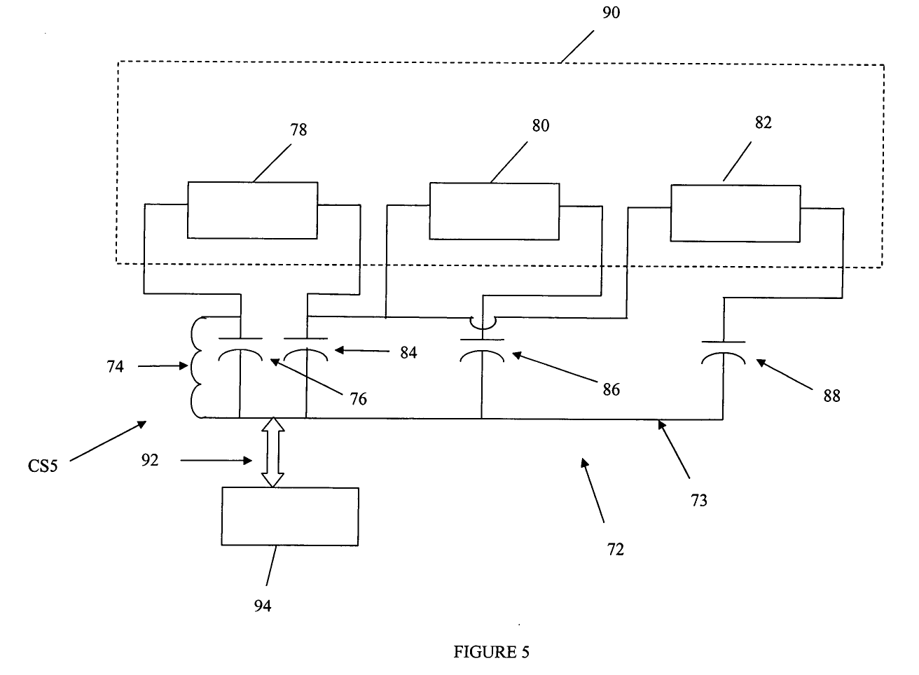

Multiple levels or grades of corrosion may be detected by using the corrosion sensor CS4. Either multiple instances of the sensor circuit 56 are replicated with different sensing element thicknesses, each instance modified to resonate at a different frequency or pair of frequencies, or a single resonant circuit is placed in parallel with multiple different inductors and/or capacitors, each in series with a different sensing element. The resulting resonant frequency would be a function of all the inductors and capacitors, and the states of corrosion of all the individual sensing elements. An embodiment of such corrosion sensor CS5 is shown schematically in FIG. 5. As shown, a sensor circuit 72 includes a communication circuit 73, functioning as a resonant circuit and including an inductor 74 and a capacitor 76 chosen to resonate at a predetermined resonant frequency, and preferably three additional capacitors or inductors 84, 86 and 88. Preferably, three sensing elements 78, 80 and 82 of different thicknesses are placed in series with corresponding capacitors or inductors 84, 86 and 88, and in parallel with each other and with the communication circuit 73. The sensing elements 78, 80 and 82 are exposed to a common corrosive or corrosion-suspect environment 90. The resulting resonant frequency of the sensor circuit 72 is therefore a function of the corrosion state of the all of three sensing elements 78, 80 and 82. This resonant frequency may be determined by detecting absorption or ringing of signal 92 using a reader circuit 94.

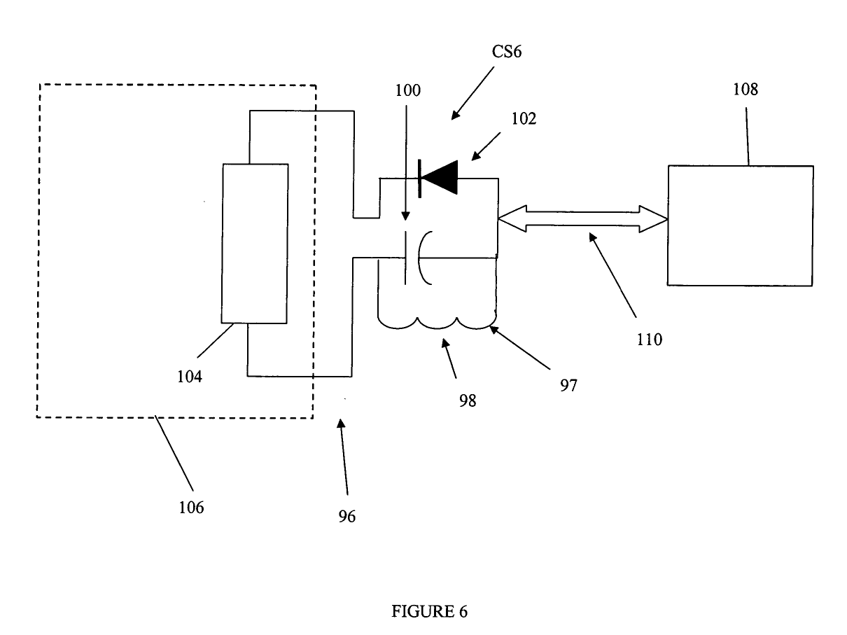

In a sixth embodiment of the corrosion sensor CS6, shown schematically in FIG. 6, a nonlinear element, such as a diode, is switched into a resonant circuit using a sensing element. Based on the state of the sensing element, harmonic frequencies of a reader-applied fundamental frequency are generated, which may be detected by the reader to determine the state of the corrosion sensor. As shown, a sensor circuit 96 includes a communication circuit 97, functioning as a resonant circuit and including an inductor 98 and a capacitor 100, and a non-linear element 102, preferably a diode. The non-linear element 102 is placed in parallel with the circuit 97, and a sensing element 104 is placed in series with the nonlinear element 97. The sensing element 104 is exposed to a corrosive or corrosion-suspect environment 106. A reader circuit 108 includes a radio-frequency circuit designed to emit radio-frequency signals 110 at or near the resonant frequency of the sensor circuit 96. The reader circuit 108 also includes a detection circuit to detect the emission of a higher harmonic (typically a third harmonic) signal 110 from the sensor circuit 96. When the sensing element 104 is uncorroded, and therefore conductive, the sensor circuit 96 generates and emits harmonic frequencies when exposed to incident radio frequency signals 110 from the reader circuit 108 at or near the resonant frequency of the circuit 96. When the sensing element 104 is corroded, and therefore nonconductive, the sensor circuit 96 does not generate harmonic frequencies, since the non-linear element is open-circuited. Depending on the presence or absence of the harmonic signal 110, the status of the sensing element 104 may be communicated to the user in a variety of conventional ways.

Alternatively, the communication circuit 97 may be modified so that the non-linear element 102 is in parallel with the sensing element 104. As a result, the non-linear element 102 will be short-circuited when the sensing element 104 is uncorroded, and will generate harmonic frequencies only when the sensing element is corroded.

The corrosion sensor CS6 may also be modified to enable the detection of multiple levels of corrosion. This may conveniently be achieved by using multiple sensor circuits 96, each tuned to a different resonant frequency, and each with a sensing element 104 of a different thickness in series with the non-linear element 102. The reader circuit 108 would then query all the resonant frequencies and detect third harmonics of the signal 110 of the resonant frequencies to determine the state of each of the corrosion sensing elements 104.

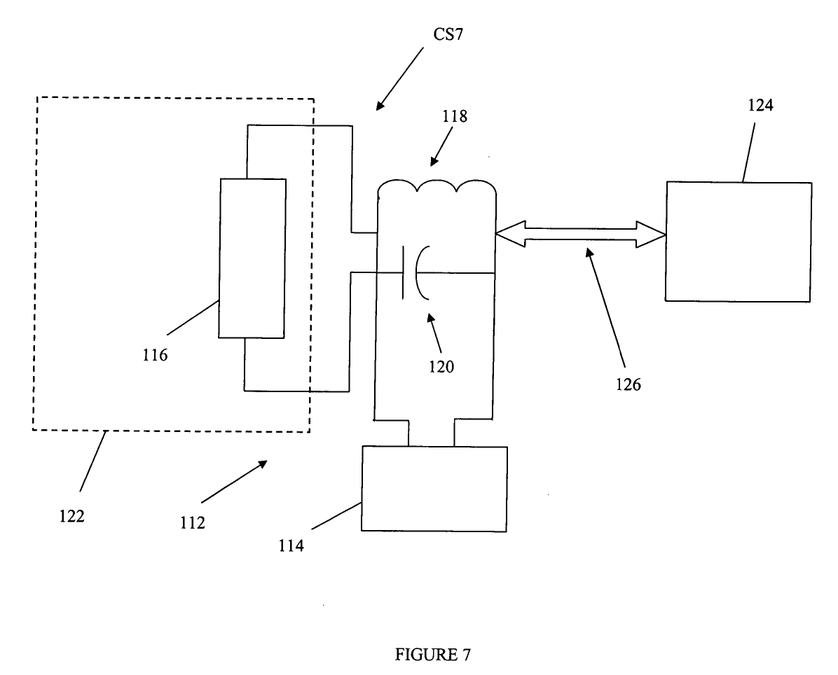

In a seventh embodiment of the corrosion sensor CS7 shown schematically in FIG. 7, one or more sensing elements are used to set the activity of one or more radio-frequency identification sensors, each equipped with a unique identification code. By reading the identification code of active sensors, the state of the one or more sensing elements can be determined. As shown, a sensor circuit 112 includes a radio-frequency identification (RFID) integrated circuit 114, preferably an RFID chip, with an external inductor and/or capacitor (not shown). A sensing element 116 is placed in series (or parallel) with the external passive components (including an inductor 118, and a capacitor or inductor 120) used in the antenna circuit. The sensing element 116 is exposed to a corrosive or corrosion-suspect environment 122. In series, when the sensing element 116 is uncorroded, the RFID circuit 114 is connected to the external passive components, and is disconnected therefrom when the sensing element 116 is corroded. In parallel, shown in FIG. 7, the passive components are short-circuited when the sensing element 116 is uncorroded, and are not short-circuited when the sensing element 116 is corroded.

Conventionally, RFID chips are designed to emit specific streams of radio-frequency signals when queried by a reader within their operating range; by either disconnecting the associated passive components, or by short-circuiting them, the RFID chip functionality is prevented, and the reader is unable to detect the streams of data. In the corrosion sensor CS7, a reader circuit 124 includes an RFID reader designed to communicate through signal 126 with the RFID chip 114. Depending on the state of the sensing element 116, the reader circuit 124 either is able to communicate via signal 126 with the RFID circuit 114, or fails to detect its presence. This information may then be communicated back to the user. Power for the RFID circuit 114 may be provided through radio frequency signals emitted by the reader circuit 124. However, it is also possible to power the sensor circuit 112 using batteries or photovoltaic cells built into the sensor circuit 112.

Multiple levels of corrosion may easily be detected by using multiple RFID circuits with associated passive components and sensor elements 116, wherein each RFID circuit is programmed to emit a different data stream. The reader circuit would determine the absence or presence of RFID circuits emitting the data streams to determine the states of the individual sensing elements 116.

Based on the above another embodiment can be envisioned where multiple corrosion sensing elements may be used to set an identifier code for a radio-frequency identification sensor. By reading this identification code using a remote reader, various states of the corrosion sensing elements can be determined. In particular, a sensor circuit would include a radio-frequency integrated circuit or chip designed to have connections to one or more sensing elements. The sensing elements may be connected between pairs of inputs on the chip, between a single input on the chip and a common terminal, such as the ground line. The chip would be designed to vary its radio-frequency output based on the state of the corrosion sensing elements. A reader would receive this radio-frequency output and determine the status of the individual sensing elements based on the data stream. This information may then be communicated to the user.

it is noted herewith that all of the above-described embodiments, may conveniently be formed as flexible circuits for mounting in or on representative corroding structures or surfaces.

### EXAMPLES

Two corrosion sensors were made in accordance with the present invention.

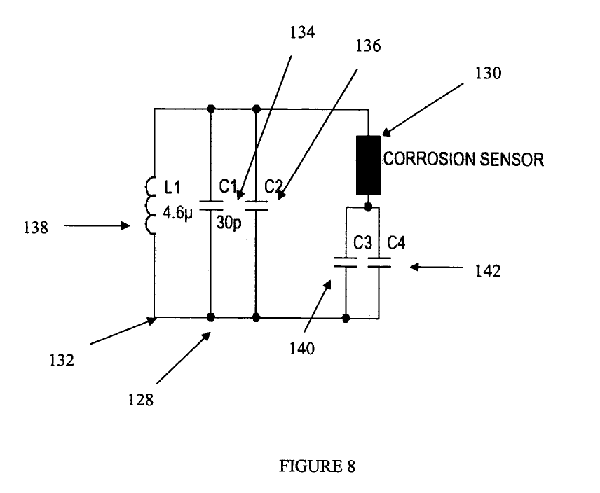

In the first example shown in FIG. 8, a sensor circuit 128 with remote corrosion detection capabilities was fabricated using a customized radio-frequency identification (RFID) sensor integrated with steel shims 130 as the sensing element. The RFID sensor included an LC tank 132 (a resonant circuit including two capacitors 134 and 136, and an inductor 138) connected to two capacitors 140 and 142. The sensing element 130 affected the resonant frequency. In particular, when the sensing element 130 was corroded, the sensor resonated at a frequency at or near 13.56 MHz. When the sensing element 130 was not corroded, it resonated at a different frequency.

A reader (not shown) emitted a radio frequency (RF) at 13.56 MHz from a loop antenna at its end, resulting in an RF field. Any conductive object that disturbed that field was detected by the reader circuit. When the sensor resonated at 13.56 MHz (due to the sensing element 130 having been entirely corroded), its presence disturbed the reader's RF field. When the sensing element 130 was not corroded, the sensor resonated at a different frequency causing no disturbance to the reader's RF field.

In the example shown in FIG. 8, the inductor 138 was a spiral trace on a planar circuit board (PCB). The capacitor was a parallel combination of four capacitors (134, 136, 140 and 142). When the sensing element 130 was not corroded, all four capacitors were used. When the sensing element 130 was corroded, only two capacitors 134 and 136 were used. The capacitors were paired to allow trimming. The capacitors 134 and 140 were selected for coarse adjustment, and capacitors 136 and 142 were added for fine adjustment of the resonant frequency. It is noted that since variation in PCB manufacture may result in some variation in the value of the inductor, a single capacitor value may not work with all sensors.

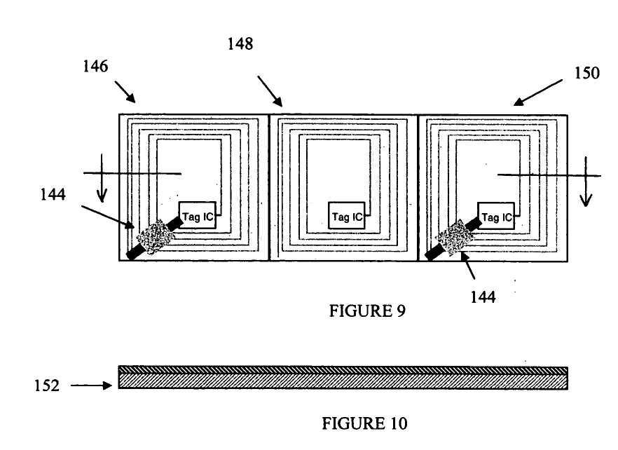

In the second example shown in FIGS. 9-10, a conventional sensor that included necessary RF circuitry for the generation of 13.56 MHz RF signals was modified to be closed with sensing elements 144, in this case, carbon steel shims. Three transponders 146, 148, 150 were packaged together with an RF shielding ferrite tape 152, and the shims 144 were only shunted in the transponders 146 and 150. The middle transponder 148 did not indicate corrosion, but, instead, indicated that the sensor was in working condition. A RF reader circuit was swept over the sensor for corrosion detection. When the shims 144 were not corroded, the sensor indicated no corrosion and the reader displayed the ID label code of the sensor. When the shims 144 were corroded, the reader did not display the ID label code of the tag, thus indicating the corrosion.

It can be observed from the above, the corrosion sensor of the present invention, enables resistive sensing of corrosion and communication of the level of corrosion to a user without a direct electrical or physical connection to a sensing element, or direct visual access to a sensing element display.

While this invention has been described as having preferred sequences, ranges, steps, materials, structures, components features, and/or designs, it is understood that it is capable of further modifications, uses and/or adaptations of the invention following in general the principle of the invention, and including such departures from the present disclosure as those come within the known or customary practice in the art to which the invention pertains, and as may be applied to the central features hereinbeforesefforth, and fall within the scope of the invention and of the limits of the appended claims.

What is claimed is:

1. A corrosion sensor, comprising:
a) a first element including a corrodible element to be exposed to a corrosive or corrosion-suspect environment; and
b) a second element including a corrosion sensing circuit coupled with said corrodible element for generating a wireless signal based on the corrosion of said corrodible element.

2. The corrosion sensor of claim 1, further comprising:
a) a third element for receiving said wireless signal; and
b) said corrosion sensing circuit and said corrodible element are coupled in series.

3. The corrosion sensor of claim 2, wherein:
a) said third element is remote from said corrosion sensing circuit and not directly connected thereto.

4. The corrosion sensor of claim 1, wherein:
a) said wireless signal comprises an electromagnetic signal.

5. The corrosion sensor of claim 1, wherein:
a) said wireless signal comprises a radio signal.

6. A corrosion sensor, comprising:
a) a first circuit for generating a wireless signal based on the extent of corrosion; and
b) a second circuit for receiving said wireless signal.

7. The corrosion sensor of claim 6, wherein:
a) said first circuit includes a first element comprising a corrodible conductor and a second element for generating a wireless signal.

8. The corrosion sensor of claim 7, comprising:
a) a plurality of said first circuits.

9. The corrosion sensor of claim 8, wherein:
a) said corrodible conductors have different thicknesses.

10. The corrosion sensor of claim 8, wherein:
a) said second elements generate signals of different frequencies.

11. The corrosion sensor of claim 6, wherein:
a) said first circuit comprises a resonant circuit.

12. The corrosion sensor of claim 6, wherein:
a) said wireless signal comprises an electromagnetic signal.

13. The corrosion sensor of claim 6, wherein:
a) said wireless signal comprises a radio signal.

14. The corrosion sensor of claim 6, wherein:
a) said second circuit comprises a portable reader.

15. A corrosion sensor, comprising:
a) a first circuit, comprising:
i) a first element comprising a corrodible conductor;
ii) a second element for generating an electromagnetic signal based on the corrosion of said corrodible conductor; and
iii) a third element for storing an electric charge;
b) a second circuit for receiving said electromagnetic signal.

16. The corrosion sensor of claim 15, wherein:
a) said first, second, and third elements are coupled such that when said conductor is corroded, said second and third elements become inactive.

17. The corrosion sensor of claim 15, wherein:
a) said first, second, and third elements are coupled such that when said conductor is corroded, said second and third elements become open-circuited.

18. The corrosion sensor of claim 15, wherein:
a) said first, second, and third elements are coupled in series.

19. The corrosion sensor of claim 15, wherein:
a) said second element comprises an inductor, and said third element comprises a capacitor.

20. The corrosion sensor of claim 15, comprising:
a) a plurality of said first circuits;
b) wherein said corrodible conductors have different thicknesses and said second elements generate signals of different frequencies.

21. A corrosion sensor, comprising:
a) a first circuit, comprising:
i) a first element comprising a corrodible conductor;
i) a second element for generating an electromagnetic signal;
ii) a third element for storing an electric charge; and
iv) a fourth element for changing the frequency of said electromagnetic signal based on the corrosion of said corrodible conductor; and
b) a second circuit for receiving said electromagnetic signal.

22. The corrosion sensor of claim 21, wherein:
a) said first, second, third, and fourth elements are coupled such that when said conductor is corroded, said fourth element becomes open-circuited.

23. The corrosion sensor of claim 22, wherein:
a) said first and fourth elements are coupled in series with each other and in parallel with said second and third elements.

24. The corrosion sensor of claim 21, wherein:
a) said first, second, third, and fourth elements are coupled such that when said first element is corroded, said fourth element becomes short-circuited.

25. The corrosion sensor of claim 24, wherein:
a) said first and fourth elements are coupled in parallel with each other and in series with said second and third elements.

26. The corrosion sensor of claim 21, wherein:
a) said second element comprises an inductor, and said third and fourth elements each comprises a capacitor.

27. The corrosion sensor of claim 21, wherein:
a) said second and fourth elements each comprise an inductor, and said third element comprises a capacitor.

28. The corrosion sensor of claim 21, comprising:
a) a plurality of said corrodible conductors of different thicknesses; and
b) a plurality of said fourth elements each coupled to a corresponding one of said corrodible conductors.

29. The corrosion sensor of claim 28, wherein:
a) said second and third elements are coupled in parallel with each of said fourth elements; and
b) each of said fourth elements is coupled in series with the corrodible conductor.

30. A corrosion sensor, comprising:
a) a first circuit, comprising:
i) a first element comprising a corrodible conductor;
ii) a second element for generating an electromagnetic signal having a first frequency;
iii) a third element for storing an electric charge; and
iv) a fourth element for creating a second frequency within said electromagnetic signal based on the corrosion of said corrodible conductor; and
b) a second circuit for receiving said electromagnetic signal.

31. The corrosion sensor of claim 30, wherein:
a) said first, second, third, and fourth elements are coupled such that when said conductor is corroded, said fourth element becomes open-circuited.

32. The corrosion sensor of claim 31, wherein:
a) said first and fourth elements are coupled in series with each other and in parallel with said second and third elements.

33. The corrosion sensor of claim 30, wherein:
a) said first, second, third, and fourth elements are coupled such that when said conductor is corroded, said fourth element becomes short-circuited.

34. The corrosion sensor of claim 33, wherein:
a) said first and fourth elements are coupled in parallel with each other and in series with said second and third elements.

35. The corrosion sensor of claim 30, wherein:
a) said second element comprises an inductor, said third element comprises a capacitor, and said fourth element comprises a non-linear element.

36. The corrosion sensor of claim 30, wherein:
a) said second element comprises an inductor, said third element comprises a capacitor, and said fourth element comprises a diode.

37. The corrosion sensor of claim 30, comprising:
a) a plurality of said first circuits;
b) wherein said corrodible conductors have different thicknesses and said second elements generate signals of different frequencies.

38. A corrosion sensor, comprising:
a) a first circuit, comprising:
i) a first element comprising a corrodible conductor;
ii) a second element for supplying power to said first circuit;
iii) a radio-frequency identification member for generating a wireless signal; and
b) a second circuit for receiving said signal.

39. The corrosion sensor of claim 38, wherein:
a) said first element, said second element, and said radio-frequency identification member are coupled such that when said conductor is corroded, said radio-frequency identification member becomes open-circuited.

40. The corrosion sensor of claim 39, wherein:
a) said first element and said radio-frequency identification member are coupled in series with each other and in parallel with said second element.

41. The corrosion sensor of claim 38, wherein:
a) said first and second elements, and said radio-frequency identification member are coupled such that when said conductor is corroded, said radio-frequency identification member becomes short-circuited.

42. The corrosion sensor of claim 41, wherein:
a) said first element and said radio-frequency identification member are coupled in parallel with each other and in series with said second element.

43. The corrosion sensor of claim 38, wherein:
a) said second element comprises an inductor.

44. The corrosion sensor of claim 38, comprising:
a) a plurality of said corrodible conductors of different thicknesses;
b) a plurality of said radio-frequency identification members coupled to a corresponding one of said conductors; and
c) wherein said radio-frequency identification members generate signals of different frequencies.

45. The corrosion sensor of claim 38, comprising:
a) a plurality of said corrodible conductors coupled to said radio-frequency identification member.

46. A corrosion sensor circuit, comprising:
a) a conductor to be exposed to a corrosive or corrosion-suspect environment;
b) said conductor having a resistance valve that varies as said conductor is corroded;
c) a wireless signal generator coupled to said conductor for generating a signal based on the resistance value of said conductor.

47. The corrosion sensor of claim 46, wherein:
a) said conductor and said wireless signal generator are coupled in series.

48. A method of monitoring corrosion, comprising:
a) providing a corrodible conductor having a resistance value that varies as the conductor is corroded;
b) coupling a wireless signal generator to the conductor;
c) exposing the conductor to a corrosive or corrosion-suspect environment; and
d) generating a signal based on the resistance value of the conductor to determine corrosion.

49. The method of claim 48, wherein:
the step a) comprises providing a plurality of corrodible conductors of different resistance values.

50. The method of claim 48, wherein:
the step a) comprises providing a plurality of corrodible conductors of different thicknesses.

51. The method of claim 48, wherein:
the step b) comprises coupling the wireless signal generator in series with the conductor.

52. The method of claim 51, wherein:
the step d) comprises sending a radio-frequency signal to the wireless signal generator for generating a response signal.

53. The method of claim 52, wherein:
the strength of the response signal indicates the level of corrosion.

54. The method of claim 48, further comprising:
placing the conductor in or about a structure for monitoring the corrosion thereof.

55. A method of monitoring corrosion, comprising:
a) providing a corrodible conductor having a resistance value that varies as the conductor is corroded;
b) coupling a wireless signal absorber to the conductor;
c) coupling a power storing member to the absorber;
d) sending a radio-frequency signal to the absorber; and
e) measuring the amount of absorption to determine corrosion.

56. A method of monitoring corrosion, comprising:
a) providing a corrodible conductor having a resistance value that varies as the conductor is corroded;
b) coupling a wireless signal generator to the conductor;
c) coupling a power storing member to the generator;
d) sending a radio-frequency signal to the generator; and
e) generating a signal based on the resistance value of the conductor to determine corrosion.

57. The method of claim 56, wherein:
the step a) comprises providing a plurality of corrodible conductors of different resistance values;
the step b) comprises coupling a plurality of wireless signal generators of different resonant frequencies each to a corresponding one of the conductors; and
the step c) comprises coupling a plurality of power storing members each to a corresponding one of the generators.

58. A method of monitoring corrosion, comprising:
a) providing a corrodible conductor having a resistance value that varies as the conductor is corroded;
b) coupling a wireless signal generator to the conductor;
c) coupling a power storing member to the generator;
d) coupling a frequency altering member to the conductor and the generator;
e) sending a radio-frequency signal to the generator; and
f) generating a signal of altered frequency based on the resistance value of the conductor to determine corrosion.

59. The method of claim 58, wherein:
the step a) comprises providing a plurality of corrodible conductors of different resistance values coupled to the generator; and
the step d) comprises coupling a plurality of frequency altering members each to a corresponding one of the conductors and to the generator;

60. A method of monitoring corrosion, comprising:
a) providing a corrodible conductor having a resistance value that varies as the conductor is corroded;
b) coupling a wireless signal generator to the conductor;
c) coupling a power storing member to the generator;
d) coupling a harmonic frequency member to the conductor and the generator;
e) sending a radio-frequency signal to the generator; and
f) generating a harmonic frequency based on the resistance value of the conductor to determine corrosion.

61. The method of claim 60, wherein:
the step a) comprises providing a plurality of corrodible conductors of different resistance values;
the step b) comprises coupling a plurality of wireless signal generators of different resonant frequencies each to a corresponding one of the conductors;
the step c) comprises coupling a plurality of power storing members each to a corresponding one of the generators; and
the step d) comprises coupling a plurality of harmonic frequency members each to a corresponding one of the conductors and a corresponding one of the generators.

62. A method of monitoring corrosion, comprising:
a) providing a corrodible conductor having a resistance value that varies as the conductor is corroded;
b) coupling a power supply to the conductor;
c) coupling a radio-frequency identification member for generating a wireless signal to the conductor and the power supply;
d) disconnecting the radio-frequency identification member based on the resistance value of the conductor; and
e) generating a wireless signal to determine corrosion.

63. The method of claim 62, wherein:
the step a) comprises providing a plurality of corrodible conductors of different resistance values; and
the step c) comprises coupling a plurality of radio-frequency identification members each to a corresponding one of the conductors and to the power supply.

64. A method of monitoring corrosion, comprising:
a) providing a plurality of corrodible conductors each having a resistance value that varies as the conductor is corroded;
b) coupling a power supply to the conductors;
c) coupling a radio-frequency identification member to the power supply;
d) connecting the conductors between pairs of inputs on the radio-frequency identification member; and
e) generating a wireless signal having a frequency based on the resistance value of one of the conductors.

65. A method of monitoring corrosion, comprising:
a) providing a plurality of corrodible conductors each having a resistance value that varies as the conductor is corroded;
b) coupling a power supply to the conductor;
c) coupling a radio-frequency identification member to the power supply;
d) connecting the conductors between a single input on the radio-frequency identification member and a common terminal; and
e) generating a wireless signal having a frequency based on the resistance value of one of the conductors.
